(19) United States
(12) Patent Application Publication
(10) Pub. No.: US 2005/0226315 A1
(43) Pub. Date: Oct. 13, 2005

(54) METHOD AND APPARATUS FOR TUNING EQUALIZER

(76) Inventor: Kuang-Yu Yen, Tai-Chung City (TW)

Correspondence Address: NORTH AMERICA INTELLECTUAL PROPERTY CORPORATION, P.O. BOX 506, MERRIFIELD, VA, 22116, US

(21) Appl. No.: 10/907,647

(22) Filed: Apr. 10, 2005

(30) Foreign Application Priority Data
Apr. 13, 2004 (TW) 093110260

(51) Int. Cl. H03K 5/159

(52) U.S. Cl. 375/232

(57) ABSTRACT

A method for tuning coefficients of an equalizer includes: generating an error value according to a comparison between an output signal of the equalizer and a threshold value; and performing a LMS algorithm based on the error value to adjust the coefficients of the equalizer.

### BACKGROUND OF INVENTION

1. Field of the Invention

The present invention relates to an equalizer, and more particularly, to a method and apparatus for tuning coefficients of an equalizer.

2. Description of the Prior Art

FIG. 1 illustrates the kinds of the etched pits on an optical disc. The optical disc can be a CD disc or a DVD disc. In FIG. 1, some pits may be shorter, longer, wider or narrower, than normal pits due to the drive's laser being unable to perfectly match the characteristics of the optical disc while an optical storage device writes data onto the optical disc.

For example, normal pits 102, 104 and 106 represent the result of normal-etching, while over-etching pits 112, 114 and 116, which are wider or longer than normal pits are used to portray over-etching. In addition, under-etching pits 122, 124 and 126 represent the result of under-etching, which occurs when the pits are shorter or narrower than the normal pits.

Generally, inter-symbol interference (ISI) and the above-mentioned nonlinear situation deteriorate the signal read back from the optical disc. Therefore, an equalizer is employed to improve the signal quality of the read-back signal.

However, the coefficients of the conventional equalizer within the optical storage device are fixed. The coefficients of the conventional equalizer cannot be adaptively adjusted with the real situations, so that the performance of the conventional equalizer cannot be optimal.

### SUMMARY OF INVENTION

It is therefore an objective of the claimed invention to provide a method for adjusting the coefficients of an equalizer.

According to the present invention, a method comprises: generating an error value according to a comparison between an output signal of the digital filter and a threshold value; and performing a Least Mean Square (LMS) algorithm based on the error value to adjust the coefficients of the digital filter.

According to the present invention, an adjusting device for tuning coefficients of an equalizer is disclosed comprising: a decision unit coupled to the equalizer for comparing an output signal of the equalizer and a threshold value to generate a comparison result; and a LMS calculator performing a LMS operation based on the comparison result and the output signal, and then adjusting the coefficients of the equalizer according to the result of the LMS operation.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 shows a diagram illustrating the kinds of the etched pits on an optical disc.

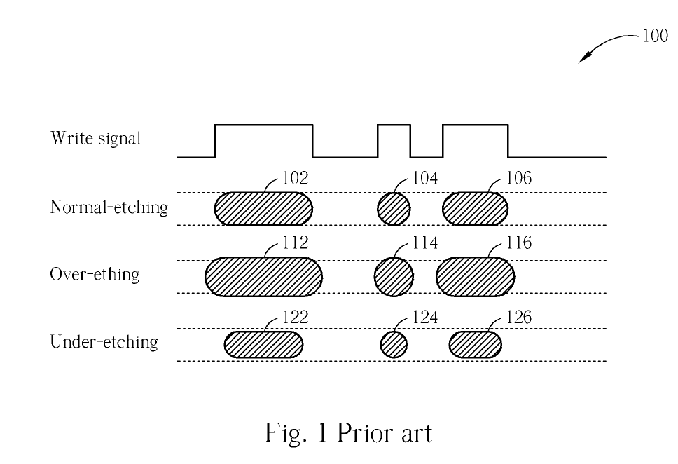

FIG. 2 is a schematic diagram of a signal processing device of an optical storage device according to the invention.

FIG. 3 is a schematic diagram of an equalizer shown in FIG. 2.

FIG. 4 shows a flowchart illustrating the coefficients of the equalizer adjusted by an adjusting device of FIG. 2.

FIG. 5 shows an eye diagram of the equalizer of FIG. 2.

FIG. 6 is a detailed block diagram of the adjusting device of FIG. 2.

### DETAILED DESCRIPTION

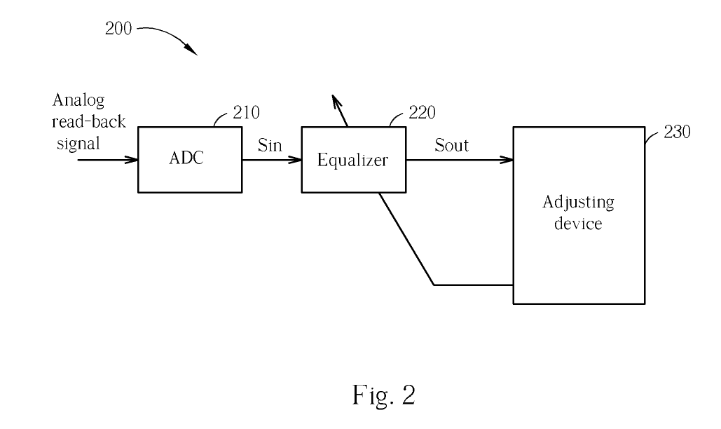

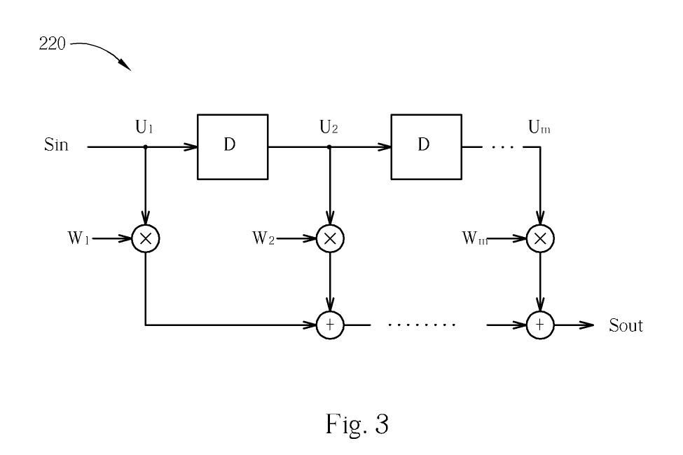

FIG. 2 is a schematic diagram of a signal processing device 200 of an optical storage device of the present invention. The signal processing device 200 comprises an analog-to-digital converter (ADC) 210 for converting a read-back signal of a CD disc or a DVD disc into a digital signal Sin; an equalizer 220 for equalizing the digital signal Sin to generate an equalized signal Sout; and an adjusting device 230 for adaptively adjusting the coefficients of the equalizer 220 to improve the performance of the equalizer 220. In an embodiment, the equalizer 220 is a digital filter. In a preferred embodiment, the digital filter can be implemented with a linear filter, as shown in FIG. 3, so as to reduce cost.

In general, a well known LMS algorithm can be represented as follows:
e(n)=d(n)−Ŵ^{H}(n)·U(n)
Ŵ(n+1)=Ŵ(n)+μ·U(n)·e*(n)
Wherein d(n) is a desired response of the output signal at time n. U(n) is a tap-input vector of the digital filter 220 at time n, and (is an estimate of a tap-weight vector of the digital filter 220 at time n. At time n, the digital filter 220 equalizes the input signal U(n) based on the coefficient Ŵ(n) to output the equalized signal Sout, which is represented as Ŵ^{H}(n)·U(n). e(n) is the difference between the desired output d(n) and actual output Ŵ^{H}(n)·U(n) at time n. μ is a step-size parameter and Ŵ(n+1) is an estimate of tap-weight vector of the digital filter 220 at time n+1.

The adjusting device 230 can adaptively adjust the coefficients of the digital filter 220 based on the LMS algorithm above. However, it is difficult to precisely measure the d(n) of this LSM algorithm.

When a CD/DVD device demodulates the output signal Ŵ^{H}(n)·U(n), it only needs to determine the binary value of the output signal Ŵ^{H}(n)·U(n), i.e., to determine the sign of the output signal. In addition, the greater difference between the positive value and negative value of the equalized signal Sout means better signal quality. For example, in an eye diagram, bigger eyes represent better signal quality. Therefore, in an embodiment, the adjusting device 230 executes a LMS algorithm when the absolute value of the output signal Sout is less than a threshold value f. In other words, when the difference between the output signal and the DC level is less than the threshold value f, the adjusting device 230 uses the value of the output signal to perform a LMS algorithm to adjust the coefficients of the digital filter 220. The LMS algorithm employed in the preferred embodiment of the present invention can be represented as follows:

$$\begin{matrix}e ( n ) = \{ \begin{matrix}sign ( {\hat{W}}^{H} ( n ) \cdot U ( n ) ) - {\hat{W}}^{H} ( n ) \cdot U ( n ) & for \vert {\hat{W}}^{H} ( n ) \cdot U ( n ) \vert \leq f \\ 0 & else\end{matrix} \\ \hat{W} ( n + 1 ) = \hat{W} ( n ) + μ \cdot U ( n ) \cdot {e}^{*} ( n )\end{matrix}$$

Wherein U(n) is a tap-input vector of the digital filter 220 at time n, and Ŵ(n) is an estimate of tap-weight vector of the digital filter 220 at time n. f is a threshold value. At time n, the digital filter 220 equalizes the input signal U(n) based on the coefficient Ŵ(n) to output the equalized signal Sout, which is represented as Ŵ^{H}(n)·U(n). sign(Ŵ^{H}(n)·U(n)) is a binary value of the output signal Sout. e(n) is the difference between the sign(Ŵ^{H}(n)·U(n)) and the actual output Ŵ^{H}(n)·U(n) at time n. μ is a step-size parameter. Ŵ(n) is an estimate of the tap-weight vector of the digital filter 220 at time n, and Ŵ(n+1) is an estimate of the tap-weight vector of the digital filter 220 at time n+1.

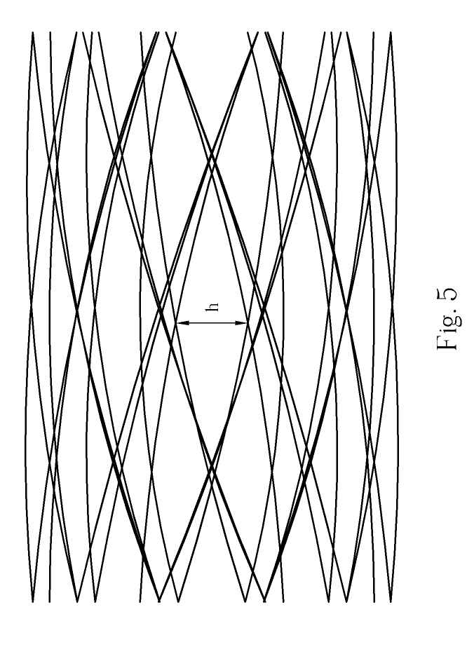

Preferably, the threshold value f is less than one half of the height of a minimum eye in an eye diagram. In an example as shown in FIG. 5, the threshold value f should be less than h/2, wherein h is the height of the minimum eye within the eye diagram.

The height h of the minimum eye within the eye diagram represents the signal quality. If the height h is greater, it means the difference between the positive value and negative value of the output signal is greater, so the signal quality is better. Therefore, the threshold value f is preferably set to a small value at the beginning of the adjustment in the coefficients of the digital filter 220. For example, the threshold value f can be set to zero at first, and is then gradually increased. In other words, at the beginning, the LMS algorithm is performed for adjusting the coefficients of the digital filter 220 only if the value of the output signal is near the DC level. In this way, the direction of coefficient adjustment will be more precise. Afterwards, even if value of the output signal is far from the DC level the LMS algorithm is performed to adjust the coefficients of the digital filter 220.

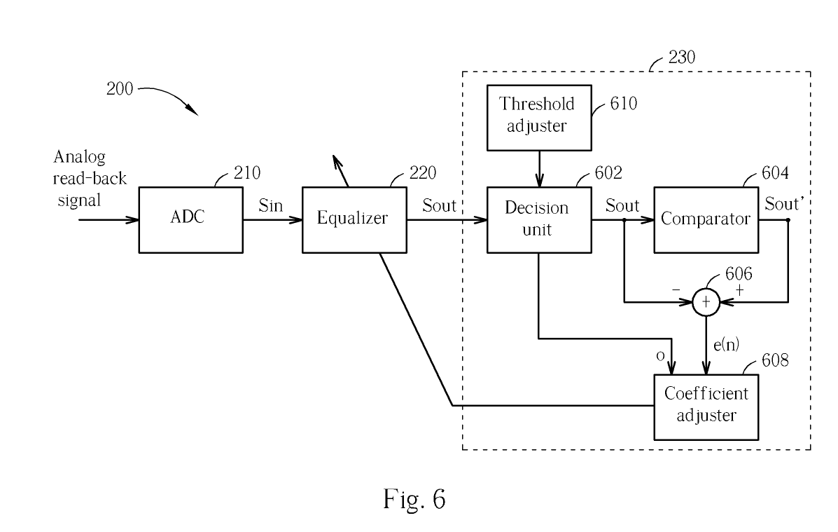

Please refer to FIG. 6, which shows a block diagram of the adjusting device 230 according to a preferred embodiment. In this embodiment, the adjusting device 230 comprises a decision unit 602, a comparator 604, an error value calculator 606, a coefficient adjuster 608 and a threshold adjuster 610.

The decision unit 602 compares the output signal Sout (i.e., Ŵ^{H}(n)·U(n)) and the threshold value f. In this embodiment, when the magnitude of the output signal Sout is greater than the threshold value f, the adjusting device 230 does not perform the LMS algorithm. In this situation, the decision unit 602 outputs a comparison result such as zero to the coefficient adjuster 608. If the magnitude of the output signal Sout is equal to or less than the threshold value f, the adjusting device 230 performs the LMS algorithm, while the decision unit 602 outputs the output signal Sout to the comparator 604. The comparator 604 compares the output signal Ŵ^{H}(n)·U(n) and a reference value (e.g., the DC level of the signal) to decide the binary value (or sign) Sout′ for the output signal Ŵ^{H}(n)·U(n). The comparator 604 performs a sign function to calculate the sign of the output signal Sout (i.e., Ŵ^{H}(n)·U(n)) of the digital filter 220. The operational result of the comparator 604 is employed as the d(n) of the LMS algorithm. In the preferred embodiment, the comparator 604 is a slicer.

The error value calculator 606 calculates the error value e(n) according to the difference between the input signal and the output signal of the comparator 604. In the preferred embodiment, the error value calculator 606 is an adder as shown in FIG. 6.

In this embodiment, when the coefficient adjuster 608 received the comparison result (e.g., 0) outputted from the decision unit 602, the coefficient adjuster 608 does not adjust the coefficients of the digital filter 220. On the contrary, when the coefficient adjuster 608 received the error value e(n) outputted from the error value calculator 606, the coefficient adjuster 608 adjusts the coefficients of the digital filter 220 according to the above-mentioned formula: Ŵ(n+1)=Ŵ(n)+μ·U(n)·e*(n).

The threshold adjuster 610 is used for adjusting the threshold value f to be input to the decision unit 602. In actual implementations, the threshold adjuster 610 could be configured to adjust the threshold value f once the adjusting device 230 executes the LMS algorithm over a predetermined number of times or a predetermined time period. As mentioned above, in this embodiment, the threshold value f is set to a small value first and is then gradually increased. The maximum value of the threshold value f is less than one half of the height h of the minimum eye in the corresponding eye diagram, i.e., h/2.

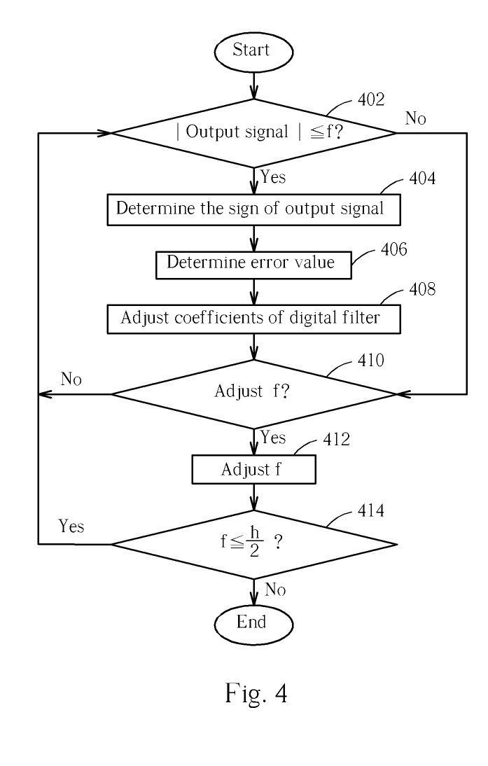

FIG. 4 shows a flowchart of adjusting the coefficients of the digital filter 220 according to the present invention. The steps of the flowchart are described as follows:

First, the decision unit 602 determines whether or not the magnitude of the output signal Sout is equal to or less than the threshold value f in step 402. If the magnitude of the output signal Sout is equal to or less than the threshold value f, the flowchart proceeds to step 404. In step 404, a binary value of the output signal Sout (i.e., Ŵ^{H}(n)·U(n)) of the digital filter 220 is determined based on a reference value ref such as the DC level of the signal. In a preferred embodiment, the comparator 604 executes the sign operation for output signal Ŵ^{H}(n)·U(n) to generate the sign value Sout′ according to the DC level. The sign value Sout′ is employed as the d(n) of the LMS algorithm. For example, when the output signal Ŵ^{H}(n)·U(n) is greater than the DC level, the comparator 604 outputs 1; when the output signal Ŵ^{H}(n)·U(n) is less than the DC level, the comparator 604 outputs −1.

The error value calculator 606 then performs step 406 to generate an error value e(n) according to the difference between the sign value Sout′, i.e., the value of d(n), and the output signal Sout.

In step 408, the coefficient adjuster 608 estimates and adjusts the coefficients of the digital filter 220 at time n+1 according to the error value e(n). In this embodiment, the coefficient adjuster 608 executes the LMS algorithm to adjust the coefficients of the digital filter 220 only when the difference between the positive value and negative value of the output signal Sout is less than the threshold value f. As mentioned above, the threshold value f is based on the height of the minimum eye in the eye diagram of the digital filter 220. For example, if the height of the minimum eye in the eye diagram of the digital filter 220 is h, the threshold value f is set to a value less than h/2. In practical implementations, an AGC is typically configured in the previous stage of the digital filter 220. The value of h can be obtained by tuning the AGC or using rule of thumb and further details are thereby omitted.

In other words, in step 408, if the absolute value of the output signal Ŵ^{H}(n)·U(n) is equal to or less than the threshold value f, it means the coefficients of the digital filter 220 are not in the ideal configuration. The coefficient adjuster 608 accordingly executes the LMS algorithm to adjust the coefficients of the digital filter 220 based on the error value e(n). On the other hand, if the output signal Ŵ^{H}(n)·U(n) is greater than the threshold value f, the coefficient adjuster 608 will not execute the LMS algorithm.

Afterwards, the flowchart proceeds to step 410. In order to improve the equalizing performance of the digital filter 220, i.e., to enlarge the eye in the eye diagram corresponding to the output signal of the digital filter 220, the threshold adjuster 610 can gradually increase the threshold value f from zero to a fixed value. In another embodiment, the threshold adjuster 610 sets the threshold value f to a value near zero (e.g., 0.1) in steps 402 through 408, and keeps track of the number of times that the coefficient adjuster 608 executes the LMS algorithm. If the number of times that the coefficient adjuster 608 executes the LMS algorithm is less than a predetermined number, this means that the difference between the positive signal and negative signal of the output signal Sout has increased to above twice the threshold value f (i.e., 0.2). In this situation, the threshold adjuster 610 executes step 412 to increase the threshold value f. For example, the threshold adjuster 610 can increase the threshold value f to 0.2. Then, steps 402 through 408 are repeatedly executed to adjust the coefficients of the digital filter 220 until the coefficient adjuster 608 executes the LMS algorithm the predetermined number of times. At that moment, the coefficients of the digital filter 220 are adjusted to a better configuration, so that the coefficient adjuster 608 stops executing the LMS algorithm.

In another embodiment, if the coefficient adjuster 608 executes the LMS algorithm within a predetermined time period, it means the coefficients of the digital filter 220 are not adjusted to an ideal configuration yet given the setting of the threshold value f. Accordingly, steps 402 through 408 are then repeatedly executed. If the coefficient adjuster 608 never executes the LMS algorithm within the predetermined time period, it means the coefficients of the digital filter 220 have adjusted to an ideal configuration given the setting of the threshold value f. In this situation, step 412 is executed to increase the threshold value.

In this embodiment, since the threshold value f is limited to less than one half of the height of the minimum eye in the eye diagram, step 414 is executed after the threshold value f is increased, in order to check if the increased threshold value f is still smaller than h/2. If the increased threshold value f is smaller than h/2, the execution of above steps is allowed; otherwise, the adjustment of the coefficients of the digital filter 220 is finished.

Those skilled in the art will readily observe that numerous modifications and alterations of the device and method may be made while retaining the teachings of the invention. Accordingly, the above disclosure should be construed as limited only by the metes and bounds of the appended claims.

1. A method for tuning coefficients of an equalizer comprising:
generating an error value according to a comparison between an output signal of the equalizer and a threshold value; and
performing a Least Mean Square (LMS) algorithm based on the error value to adjust the coefficients of the equalizer.

2. The method of claim 1, wherein the error value is zero if the magnitude of the output signal is greater than the threshold value.

3. The method of claim 1, wherein if the magnitude of the output signal is equal to or less than the threshold value, the error value is decided by following steps:
performing a sign operation for the output signal; and
calculating the error value according to the result of the sign operation.

4. The method of claim 1, further comprising:
adjusting the threshold value.

5. The method of claim 4, wherein the threshold value is adjusted when the LMS algorithm is executed over a predetermined number of times or a predetermined time period.

6. The method of claim 1, wherein the threshold value is less than one half of the height of a minimum eye in the eye diagram of the equalizer.

7. The method of claim 1, wherein the output signal is read back from a CD disc or a DVD disc.

8. An adjusting device for tuning coefficients of an equalizer, the adjusting device comprising:
a decision unit, coupled to the equalizer, configured to compare an output signal of the digital filter and a threshold value to generate a comparison result; and
a least mean square (LMS) calculator, coupled to the decision unit configured to perform a LMS operation based on the comparison result and the output signal and to adjust coefficients of the equalizer according to the result of the LMS operation.

9. The adjusting device of claim 9, wherein the equalizer is a digital filter.

10. The adjusting device of claim 9, wherein the LMS calculator further comprises:
a comparator to perform a sign operation for the output signal to generate a sign value;
an error value calculator to generate an error value according to the sign value and the output signal; and
a coefficient adjuster to perform a LMS algorithm to adjust the coefficients of the digital filter according to the comparison result and the error value.

11. The adjusting device of claim 10, wherein the coefficient adjuster does not adjust the coefficients of the digital filter when the magnitude of the output signal is greater than the threshold value.

12. The adjusting device of claim 10, wherein the coefficient adjuster adjusts the coefficients of the digital filter when the magnitude of the output signal is equal to or less than the threshold value.

13. The adjusting device of claim 10, wherein the comparator comprises a slicer.

14. The adjusting device of claim 10, wherein the error value calculator comprises an adder.

15. The adjusting device of claim 9, further comprising:
a threshold adjuster to adjust the threshold value.

16. The adjusting device of claim 15, wherein the threshold adjuster adjusts the threshold value when the coefficient adjuster executes the LMS algorithm over a predetermined number of times or a predetermined time period.

17. The adjusting device of claim 16, wherein the threshold adjuster is used for increasing the threshold value.

18. The adjusting device of claim 16, wherein the threshold value is less than one half of the height of a minimum eye in the eye diagram of the digital filter.

19. The adjusting device of claim 9, wherein the operation of the LMS calculator is capable of being represented as follows:
$$\begin{matrix}e ( n ) = \{ \begin{matrix}sign ( {\hat{W}}^{H} ( n ) \cdot U ( n ) ) - {\hat{W}}^{H} ( n ) \cdot U ( n ) & for \vert {\hat{W}}^{H} ( n ) \cdot U ( n ) \vert \leq f \\ 0 & else\end{matrix} \\ \hat{W} ( n + 1 ) = \hat{W} ( n ) + μ \cdot U ( n ) \cdot {e}^{*} ( n )\end{matrix}$$
wherein [symbol] is a tap input vector of the digital filter; Ŵ(n) is a tap-weight vector of is the output signal; f is the threshold value; sign(Ŵ^{H}(n)·U(n) is the result of a sign operation for the output signal; e(n) size parameter.

20. The adjusting device of claim 9, wherein the digital filter is used for processing a signal read back from a CD disc or a DVD disc.
